(19) United States
(12) Patent Application Publication
(10) Pub. No.: US 2005/0206896 A1
(43) Pub. Date: Sep. 22, 2005

(54) Materials classifier, method of making, and method of using

(76) Inventor: Scott Sibbett, Corrales, NM (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/133,401

(22) Filed: May 18, 2005

Related U.S. Application Data
(63) Continuation of application No. 10/024,674, filed on Dec. 17, 2001, now abandoned.

(51) Int. Cl. H01L 31/0328

(52) U.S. Cl. 356/335

(57) ABSTRACT

The present invention relates to a method of classifying charged molecules such as proteins for quantitative analysis. An aliquot of a body serum is subjected to separation forces may be fluid drag and electrophoretic force in opposition.

### RELATED APPLICATIONS

This application is a continuation of Ser. No. 10/024,674, filed Dec. 17, 2001, entitled “Materials Classifier, Method of Making, and Method of Using.”

### FIELD OF THE INVENTION

The present invention relates to a particle classifier. More particularly, the present invention relates to separation of variably charged molecules in a fluid. In particular, the present invention relates to a method of classifying zwitterions in a fluid that contrasts a convective force against an electromotive force.

### BACKGROUND OF THE INVENTION

Description of Related Art

One current primary method for separation of charged molecules in solution such as proteins is 2-dimensional polyacrylamide gel electrophoresis (PAGE). This method requires a laborious multi-step preparation of unstable gels, followed by extensive manual working of the gels by skilled technicians. Quantification of the separated molecules is performed typically by visual or photographic inspection of the resulting gels.

A second common method for separation of charged molecules in solution is matrix assisted laser desorption ionization (MALDI) mass spectrometry. This method does not require gels or gel manipulation to separate and quantify a mixture of charged molecules. However, it requires sophisticated vacuum chamber technology, and therefore is too cumbersome for use anywhere but a dedicated laboratory environment, and requires an expensive hardware investment.

Another technique uses micro fabricated structures. Capillary electrophoresis, synchronized cyclic electrophoresis, free-flow electrophoresis, and capillary gel electrophoresis have been demonstrated to separate ions. Another technique includes digital field gradient focusing (DFGF).

### BRIEF DESCRIPTION OF THE DRAWINGS

In order that the manner in which the above recited and other advantages of the invention are obtained, a more particular description of the invention briefly described above will be rendered by reference to specific embodiments thereof which are illustrated in the appended drawings. Understanding that these drawings depict only typical embodiments of the invention that are not necessarily drawn to scale and are not therefore to be considered to be limiting of its scope, the invention will be described and explained with additional specificity and detail through the use of the accompanying drawings in which:

FIG. 1 is a cross section of a device during fabrication according to an embodiment;

FIG. 2 is a cross section of the device depicted in FIG. 1 after further processing;

FIG. 3 is a cross section of the device depicted in FIG. 2 after further processing;

FIG. 4 is a first cross section of the device depicted in FIG. 3 after further processing, depicted in a first plane;

FIG. 5 is a second cross section of the device depicted in FIG. 3 after further processing, depicted in a second plane that is located above the first plane depicted in FIG. 4;

FIG. 6 is a perspective view of a portion of the device that illustrates partial views depicted in FIGS. 4 and 5;

FIG. 7 is a cross section of a device during fabrication according to an embodiment;

FIG. 8 is a cross section of the device depicted in FIG. 7 after further processing; and

FIG. 9 is a process flow block diagram of the inventive process.

### DETAILED DESCRIPTION OF THE INVENTION

The present invention relates to a charged molecule classifier that operates with electromotive and convective forces. The present invention is advantageous because it eliminates the need for preparation of gels, eliminates gel instability, eliminates manual working of gels, and enables automated quantification of the charged molecules. Accordingly, the present invention provides a solid state charged molecule classifier, a method of fabricating it, and a method of classifying charged molecules in a fluid.

The inventive classifier described herein may be manufactured at various scales. Embodiments of the classifier include silicon structures, inorganic dielectric structures such as silica, and organic dielectric structures such as plastic. The present invention is particularly advantageous at micro electromechanical structure (MEMS) scale. Many features of the inventive charged molecule classifier may be incorporated from standard components of MEMS technology, for example, microfluidic channels, electrodes, and detectors.

The following description includes terms, such as upper, lower, first, second, etc. that are used for descriptive purposes only and are not to be construed as limiting. The embodiments of a device or article of the present invention described herein can be manufactured, used, or shipped in a number of positions and orientations. The term “substrate” generally refers to the physical object that is the basic workpiece that is transformed into the desired article by various process operations. A substrate may be made of silica glass or the like, or it may be made of plastic. A substrate may also be referred to as a wafer. Wafers may be made of semiconducting, non-semiconducting, or combinations of semiconducting and non-semiconducting materials.

Reference will now be made to the drawings wherein like structures will be provided with like reference designations. In order to show the structures of the present invention most clearly, the drawings included herein are diagrammatic representations of inventive articles. Thus, the actual appearance of the fabricated structures, for example in a photomicrograph, may appear different while still incorporating the essential structures of the present invention. Moreover, the drawings show only the structures necessary to understand the present invention. Additional structures known in the art have not been included to maintain the clarity of the drawings.

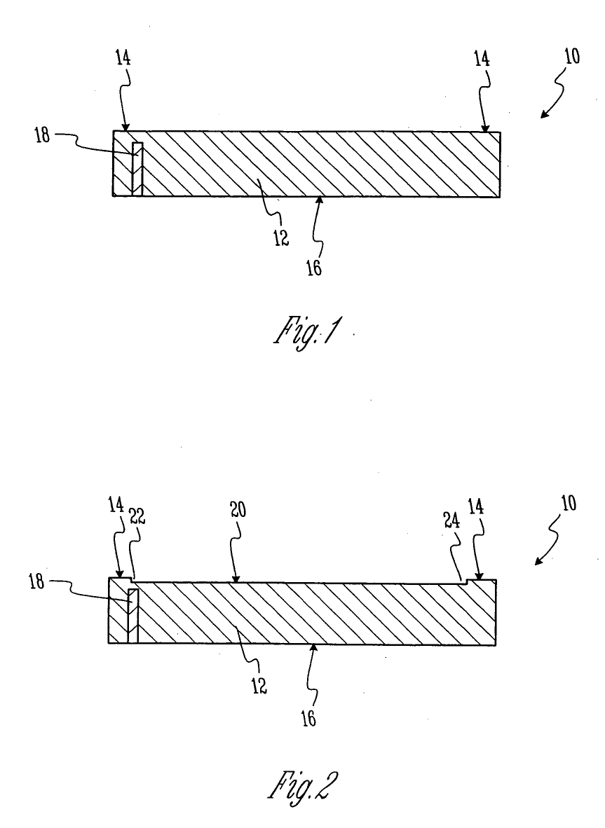

FIG. 1 illustrates the beginning of fabrication of a device 10 for classifying charged molecules according to an embodiment. In a cross-sectional view, a first substrate 12 is provided with a top surface 14, a bottom surface 16, and a first or ground electrode 18 that communicates to the bottom surface 16. First electrode 18, in other embodiments, may communicate to other surfaces and is depicted as communicating to bottom surface 16 in this embodiment. Although first electrode 18 is depicted as being formed in device 10 at FIG. 1, it may be formed later according to selected process integrations.

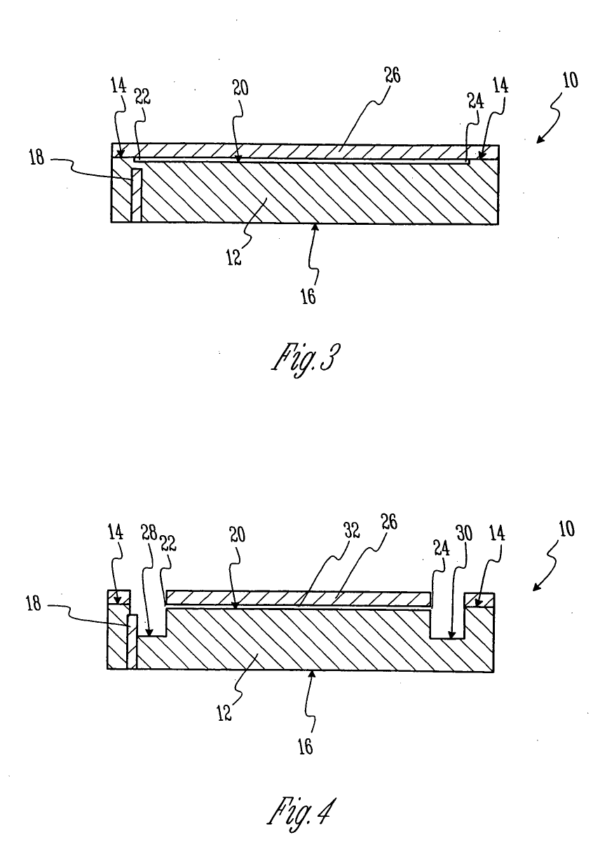

FIG. 2 illustrates further processing upon device 10. A first recess 20 is formed in substrate 12 that extends laterally to include a first end 22 and a second end 24. First recess 20 is an elongated trench that will later be enclosed to form an elongated conduit. After formation of first recess 20, further processing includes forming a conduit by covering the first substrate 12 with a second substrate 26 as depicted in FIG. 3. First substrate 12 and second substrate 26 are each dielectric materials. In one embodiment, first substrate 12 and second substrate 26 are silica glass. In another embodiment, first substrate 12 and second substrate 26 are semiconductive material that allows integrated circuitry to be formed thereon. The integrated circuitry may be formed at various scales depending upon the available area presented by surfaces of device 10. In one embodiment, an integrated circuit is formed upon a surface (not pictured) of second substrate 26. In another embodiment, a pick-and-place integrated circuit package or the like is used and mounted upon device 10 at an available surface (not pictured).

In another embodiment, first substrate 12 and second substrate 26 are an organic dielectric material such as suitable plastic substrates having neutral surfaces such as parylene, which is commonly used for the fabrication of compact disks (CDs) and digital video disks (DVDs).

The process of forming first recess 20 may be carried out by several embodiments. In one embodiment, an etch process is carried out in silica glass according to known technique. The etch includes spinning on a photoresist, exposing, patterning, and etching through the patterned photoresist.

In one embodiment, the width (not depicted) of first recess 20 is in a range from about 1 micrometer (μ) to about 1,000μ. In another embodiment, the width of first recess 20 is from about 10μ to about 500μ. In another embodiment, the width of first recess 20 is from about 100μ to about 200μ. The selected width is tied to the volume of fluid to be analyzed and to the viscosity of the fluid, relative to the substrate material.

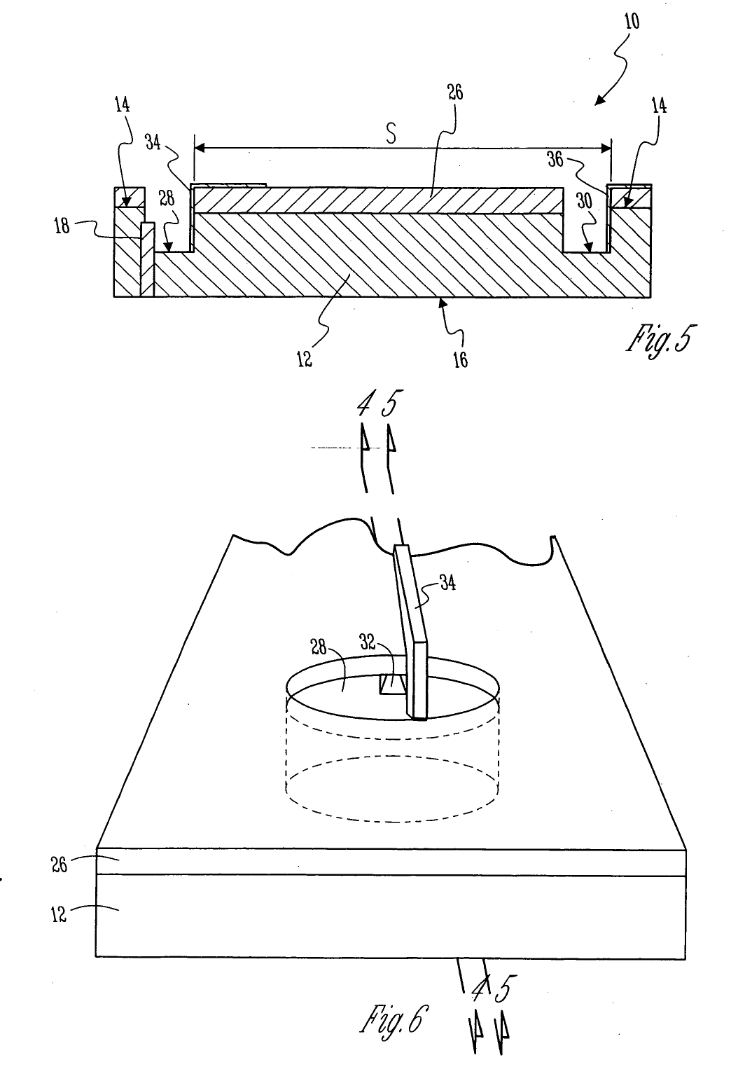

FIG. 4 illustrates further processing during which a second recess 28 and a third recess 30 are formed through second substrate 26 and into first substrate 12. Second recess 28 is formed at first end 22 of first recess 20, although first end 22 of first recess 20 has relocated farther to the right as depicted in FIG. 4 due to the process of forming second recess 28. Third recess 30 is formed at second end 24 of first recess 20, although second end 24 of first recess 20 has relocated farther to the left as depicted in FIG. 4 due to the process of forming third recess 30. In any event, second recess 28 and third recess 30 communicate to each other through first recess 20.

With the presence of second substrate 26 to enclose first recess 20, first recess has become an enclosed conduit 32 therebetween. The cross-sectional shape of conduit 32 may be rectangular, v-shaped, u-bottom shaped, or others according to selected processing embodiments.

One embodiment during fabrication is configuring conduit 32 to resist electroosmosis. Preferably, the electroosmosis is cut to about zero. One strategy is to shield the charged groups within the walls of conduit 32 that initiate electroosmosis. According to this embodiment, a neutralizing process is carried out. Where first substrate 12 is silica, it is rinsed with sodium hydroxide (NaOH) into the channel. The NaOH rinse improves the likelihood of binding a shielding material to first substrate 12. After the NaOH rinse, a hydroxypropyl methyl cellulose liner, or other such electroosmotic-suppressing coatings (not pictured) is disposed into the walls of conduit 32. Another embodiment to resist electroosmosis is to use suitable plastic substances having neutral surfaces, such as parylene. Parylene is known to have zero charge groups in its structure.

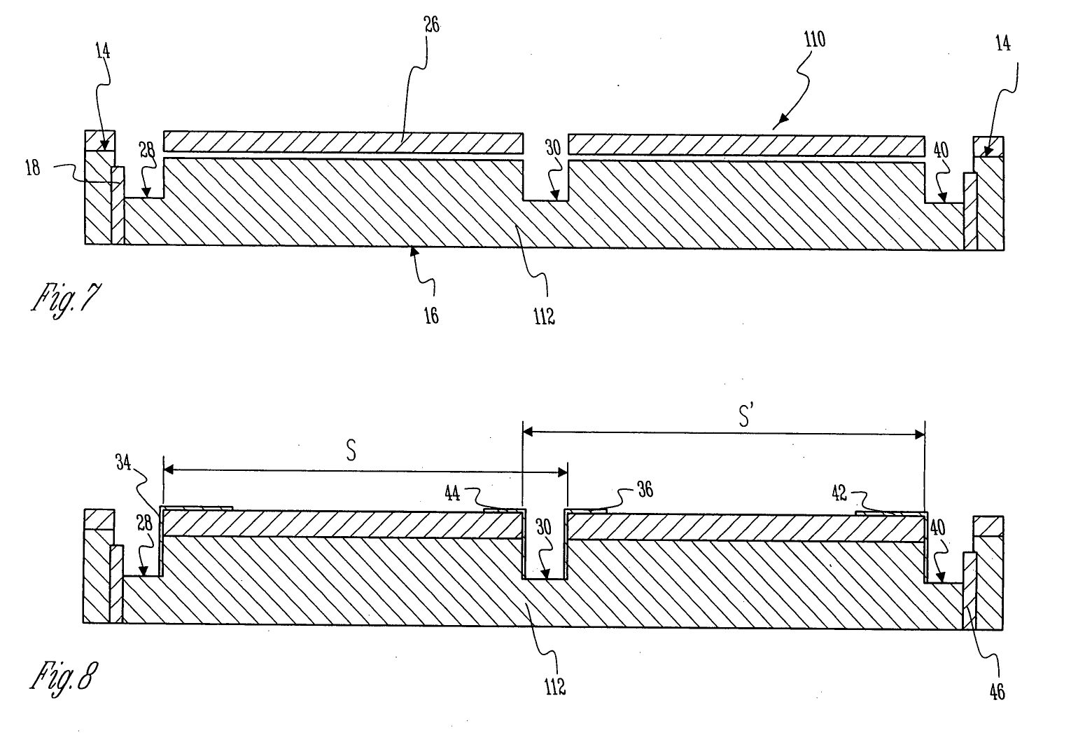

FIG. 5 depicts further processing through a new cross-section. In FIG. 5, a new cross-sectional area is depicted that is above the plane of FIG. 4. Second recess 28 and third recess 30 have been processed to form a second electrode 34 and a third electrode 36 therein, respectively. The distance, S, between second electrode 34 and third electrode 36 is used in establishing an electromotive bias therebetween for charged molecule classifying method embodiments as set forth herein. First electrode 18, second electrode 34, and third electrode 36 may also be described in their spatial relationship to first recess 28, second recess 30, and conduit 32 (shown in FIGS. 4 and 6). First electrode 18 is disposed in the fluid source reservoir (second recess 28) and spaced apart from the first end 22 of the conduit 32. Second electrode 34 is spaced apart from first electrode 18 and disposed either in the fluid source reservoir 28 proximate the conduit 32, or in conduit 32 proximate the fluid source reservoir 28. Finally, third electrode 36 is disposed in the fluid receptacle reservoir (third recess 30) and space apart from the second end 24 of conduit 32.

Second electrode 34 and third electrode 36 are configured as varactors in order to allow for adjustable biasing according to method embodiments. The formation of second electrode 34 and third electrode 36 may be done by various process flows. For example, the in-recess portions of second electrode 34 and third electrode 36 may be made by a contact hole etch and fill process. In another embodiment, second electrode 34 and third electrode 36 are fabricated in 3-dimensions by a focused ion beam (FIB) deposition technique as is known in the art. The depth into the respective recesses that second electrode 34 and third electrode 36 may be formed by FIB deposition, may depend upon the aspect ratio of second recess 28 and third recess 30.

In another embodiment, a second contact hole and a third contact hole (not pictured) are filled with an electrode material, a blanket deposition of electrode material is done above second substrate 26. Thereafter, patterning and etching is carried out to both pattern the traces of second electrode 34 and third electrode 36, and to simultaneously or subsequently etch second recess 28 and third recess 30. By the illustration of these process flow embodiments, it is understood that other process flow embodiments may be used to build device 10. By “etching” it is understood that larger-scale devices may be made wherein second recess 28 and third recess 30 may be made by other processes such as simple drilling.

FIG. 6 is a partial, perspective view of device 10 that illustrates selected features of second recess 28 and second electrode 34 as they are situated in relation to conduit 32. Accordingly, FIG. 4 is a cross-section taken along the line 44 that exposes conduit 32, and FIG. 5 is a cross-section taken along the line 55 that exposes second electrode 34. Second recess 28 acts as a fluid reservoir. Second electrode 34 (FIG. 6) and third electrodes 36 (depicted in FIG. 5), are electromotively biased in order to cause charged particles to pass through conduit 32 and to focus at or near second electrode 34.

According to an embodiment, a method of classifying particles is disclosed. In these embodiments, second recess 28 acts as a fluid source reservoir. Fluid flow therefore passes from second recess 28 as a fluid source reservoir to a fluid receptacle reservoir, meaning third recess 30.

The method of classifying particles includes placing a fluid into device 10, both into second recess 28 and into third recess 30 (FIG. 5). In a general embodiment, the fluid contains at least one protein. In one embodiment, the fluid contains at least two charged particle types such as two zwitterion proteins that have been taken from a mammalian body serum such as milk, blood, blood plasma, urine, spinal fluid, tears, saliva, intercellular fluid, or others. The fluid may contain an aliquot of a mammalian body serum, or it may be an undiluted body serum. Hereinafter, the contents of the fluid will be referred to as an aliquot, although this terminology is not to be limiting.

In one embodiment, the fluid in third recess 30 is pH-buffered and contains the particles that are to be classified, and the fluid in second recess 28 is pH-buffered and does not contain any particles that are to be classified. After placing the fluid(s) into device 10, the method continues by generating a convective force in conduit 32 between the fluid source at second recess 28 and the fluid receptacle at third recess 30. The method continues by first biasing between second electrode 34 and third electrode 36 under conditions to focus a first particle type in the fluid at second electrode 34. In one embodiment, this first biasing may be carried out by establishing a potential in a range from about 0.1 Volts (V) to about 300 V, depending upon the system. In another embodiment, the first biasing is in a range from about 100 V to about 240 V. Before, during, or after the first biasing, the convective force is established in conduit 32 that creates a force from second recess 28 toward third recess 30. Accordingly, where the biasing between second electrode 34 and third electrode 36 causes particles to be drawn toward second electrode, the convective force in the fluid is calculated to create a classifying effect upon the particle types. Therefore, a first particle type becomes mobile to successfully move against the convective force because of its electrical charge, but other particle types, because their electrical charges are different from the first particle type, do not become mobile.

According to another embodiment, after first biasing between second electrode 34 and third electrode 36, a subsequent biasing is carried out that causes a particle type that is different from the first particle type to become mobile at otherwise unchanged convective force conditions. This method of classifying particles may be repeated up to an nth biasing, wherein n is greater than or equal to 2. The nth biasing between second electrode 34 and third electrode 36 is done under conditions to focus an nth particle type in the fluid at second electrode 34.

In one embodiment, generation of the convective force is created by a pump. The pump type that is employed is dependent upon such factors as scale of the device and the flow rate. The flow rate is affected by the total volume that is in first recess 28 where pumping is directly into first recess 28. In one embodiment, a piezoelectric micropump is used that operates on positive displacement according to known technique. Other ways of establishing a flow in conduit 32 include causing a hydrostatic head sufficient to get a flow, and rotating device 10 in order to get a centrifugally induced flow.

In another embodiment, a centrifugal microfluidic pump is used according to known technique. In a device wherein the conduit 32 width is about 50μ and the length is about 10 centimeters, the flow rate through conduit is in a range from about 0.5 nanoliters/second to about 50 nanoliters/second.

In another embodiment, the first particle type includes a first plurality of particle types that all become mobile against the given convective force in conduit 32. In this embodiment, the first plurality of particle types may include various blood components such as high-density lipoproteins (HDLs), and low-density lipoproteins (LDLs). Further classification of particles in the aliquot may be carried out by subsequent incremental biasing between second electrode 34 and third electrode 36, and allowing the particles to focus at second electrode 34. Accordingly, after nth biasing, the method further includes n+1^{st} biasing between the second electrode and the third electrode under conditions to focus an n+1^{st} particle type in the fluid. Similarly, the n+1^{st} biasing may classify an n+1^{st} plurality of particle types.

Preparation of the aliquot that makes up the fluid includes pH buffering the fluid in order to establish a preferred particle charge according to the capabilities of the device. For example, as the pH changes, the net charge on a zwitterions also changes from negative to neutral, to positive, or visa versa. In one embodiment, the particles that are rendered at their isopotential state (at their isopotential, pI, or zero-charge state) are not desired to be focused and quantified. Accordingly, initial screening of the aliquot may be achieved by establishing a pH-buffered solution that renders non-selected particles non-mobile. According to this embodiment, a selected pH is established in a buffered solution that renders selected particles the most mobile. Typically, a given aliquot will contain known particle types such that a selected pH will configure the aliquot for a preferred analysis. In other words, the aliquot will have known substances therein.

In another embodiment, a multi-particle analysis may be preferred. In this method, a first particle type is focused at second electrode 34 as set forth herein and the amount of the first particle type is quantified. Thereafter, a second particle type is also focused at second electrode 34, and the amount of the second particle type may be quantified by measuring the amount of particles at second electrode 34, and subtracting the known amount of the first particle type.

The following is a first method example according to an embodiment. For this embodiment, reference may be made to FIGS. 4-6. A fluid is placed into a device 10 by filling second recess 28 with a pH-buffered fluid and third recess 30 with the pH-buffered fluid that is an aliquot of three or more particle types. The distance, S, between second electrode 34 and third electrode 36 is about 10 cm. The width of conduit 32 is about 37μ and the height is about 20μ. The three particle types have characteristics of absolute mobility and net charge as set forth in Table 1.

TABLE 1
Particle Characteristics

| Particle Type | ω, cm²/(V sec) | Net Charge |
|---|---|---|
| P1 | 1E−4 | −250 |
| P2 | 5E−5 | −200 |
| P3 | 1E−5 | −100 |

A pump (not pictured) is employed at second recess 28 that establishes a flow rate of about 20 nanoliters/second. A first biasing is carried out by applying a 100 V differential between second electrode 34 and third electrode 36. P1 moves out of third recess 30 and traverses through conduit 32 and is the first to focus at second electrode 34 after about four seconds. P2 and P3 are relatively immobile with respect to P1 because the convective force holds them in third recess 30 and prevents them from flowing through conduit 32. However, because of its mobility, P2 eventually can move out of third recess 30 and traverse conduit 32. Accordingly if allowed to, P2 is the second particle type to focus at second electrode 34 after about 10 seconds. Finally if allowed to, P3 can move out of third recess 30 and traverse conduit 32. Accordingly if allowed to, P3 is the third particle type to focus at second electrode 34 after about 100 seconds. At each interval, a quantification is done to detect the amount of particles that has focused.

In a second method example, the same processing is done as in the first method example, except after P1 has focused and has been quantified, the potential is increased to about 240 V and P2 focuses at second electrode after about four more seconds.

In a third method example, the same processing is done as in the first method example, except after P2 has focused and has been quantified, the potential is increased to about 240 V and P3 focuses at second electrode after about 42 seconds.

Other embodiments of include charged particle movement and focusing where first electrode 18 may be changed out as the ground electrode with second electrode 34 or third electrode 36. Table 2 illustrates 16 method examples that are similar in operation to other examples set forth herein, with this variable-ground-electrode difference. Net positive-charge particles are P+ and net negative-charge particles are P-. R1 represents second recess 28, and R2 represents third recess 30.

TABLE 2
Changeable Ground Electrode Particle Movement and/or Focusing

| | Fluid | setting | Setting | Setting | Analyte | | |
|---|---|---|---|---|---|---|---|
| Example | flows | for | for | for | starting | | |
| number | toward* | E1 | E2 | E3 | point | Fate of P⁺ | Fate of P− |
| 1 | → | ground | + | +++ | R1 | focusable | move to other |
| | | | | | | | reservoir |
| 2 | → | ground | + | +++ | R2 | focusable | stay in place |
| 3 | → | ground | − | −−− | R1 | move to other | focusable |
| | | | | | | reservoir | |
| 4 | → | ground | − | −−− | R2 | stay in place | focusable |
| 5 | → | +++ | + | ground | R1 | focusable | focusable |
| 6 | → | +++ | + | ground | R2 | stay in place | focusable |
| 7 | → | −−− | − | ground | R1 | focusable | focusable |
| 8 | → | −−− | − | ground | R2 | focusable | stay in place |
| 9 | [symbol] | ground | + | +++ | R1 | stay in place | focusable |
| 10 | [symbol] | ground | + | +++ | R2 | focusable | focusable |
| 11 | [symbol] | ground | − | −−− | R1 | focusable | stay in place |
| 12 | [symbol] | ground | − | −−− | R2 | focusable | focusable |
| 13 | [symbol] | +++ | + | ground | R1 | stay in place | focusable |
| 14 | [symbol] | +++ | + | ground | R2 | focusable | move to other |
| | | | | | | | reservoir |
| 15 | [symbol] | −−− | − | ground | R1 | focusable | stay in place |
| 16 | [symbol] | −−− | − | ground | R2 | move to other | focusable |
| | | | | | | reservoir | |

*the → and [symbol] symbols relate to the Figures.

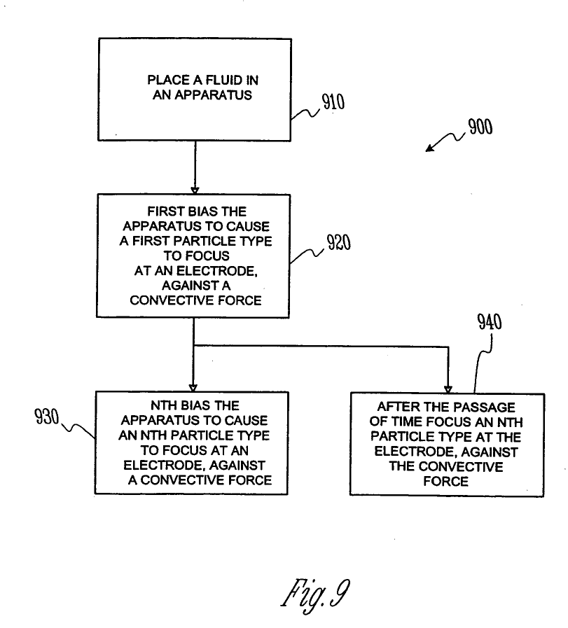

In another embodiment, depicted in FIGS. 7 and 8, the analytical technique may require isolation of a first particle type from a second particle type and the quantification of either or both of them. Additionally, another class of particles may be rendered to their isopotential point, pI, before classification is carried out. First, according a process flow for fabricating the device, first-through-fourth recesses 20, 28, 30, and 40, respectively are formed as depicted in FIG. 7. Then, as depicted in FIG. 8, second-through fifth electrodes 34, 36, 42, and 44, respectively are formed in their respective recesses according to embodiments set forth herein. Similar to first electrode 18, an optional second ground electrode or sixth electrode 46 may be disposed in substrate 112 for operational advantages.

In this embodiment, the first biasing is carried out between second electrode 34 and third electrode 36 that causes a first particle type to focus at second electrode 34. Next, a second biasing is carried out between fourth electrode 42 and fifth electrode 44 at a distance, S′, that causes a second particle type to focus at fourth electrode 42. The distance S′ may be equal to the distance S. It can now be seen that the above techniques may be combined to group focus various particle types and/or to group isolate various particle types at selected electrodes according to a given application.

As set forth herein, various analytical techniques may be done to quantify the focused particles. Typically, a known system of particle types is to be classified such that a variable-opacity and/or colorimetric optical analysis may suffice to quantify the particles that have focused. In any event, analyzing the particle types is done by a method selected from quantitative analysis, qualitative analysis, or a combination thereof.

Another embodiment relates to a system. The system includes embodiments of the device as set forth herein, and it includes the fluid and optionally the pumping source. The hydrostatic head or the centrifugal motion methods may also be selected as part of the system.

FIG. 9 illustrates a process flow embodiment 900. In a first process flow, a fluid is placed 910 in a device or apparatus according to embodiments set forth herein. Next, a first bias is established 920 between electrodes to cause a first particle type to focus against a convective force. Thereafter, an Nth bias is established 930 between electrodes to cause an Nth particle type to focus against the convective force. In a second process flow embodiment, the process 910 is repeated, followed by allowing the passage of time 940, during which an Nth particle focuses against the convective force.

It will be readily understood to those skilled in the art that various other changes in the details, material, and arrangements of the parts and method stages which have been described and illustrated in order to explain the nature of this invention may be made without departing from the principles and scope of the invention as expressed in the subjoined claims.

1. A method of classifying particles, comprising:
placing a fluid into a device, wherein the fluid contains at least two particle types, and wherein the device includes a first electrode, a second electrode, a third electrode, and a conduit disposed between the second electrode and the third electrode;
first biasing between the second electrode and the third electrode under conditions to focus a first particle type; and
nth biasing between the second electrode and the third electrode under conditions to focus an nth particle type.

2. The method according to claim 1, wherein first biasing under conditions to focus a first particle type includes a first particle type that includes a first plurality of particle types.

3. The method according to claim 1, wherein first biasing under conditions to focus a first particle type includes a first particle type that includes a first plurality of particle types, and following nth biasing, further including:
n+1^{st} biasing between the second electrode and the third electrode under conditions to focus an n+1^{st} particle type.

4. The method according to claim 3, wherein n+1^{st} biasing under conditions to focus a first particle type includes an n+1^{st} particle type that includes an n+1^{st} plurality of particle types.

5. The method according to claim 1, further including:
establishing a convective force in the fluid, wherein the convective force directs the fluid into the conduit.

6. The method according to claim 1, further including:
establishing a convective force in the fluid, wherein the convective force directs the fluid into the conduit, wherein the conditions to focus a particle type include an electrophoretic mobility for a given particle type that overcomes the convective force in the conduit, and wherein the particle type focuses at the second electrode.

7. The method according to claim 1, wherein the first electrode includes a ground, wherein the second electrode includes a varactor, and wherein the third electrode includes a varactor.

8. The method according to claim 1, wherein the fluid is pH-buffered.

9. The method according to claim 1, wherein the at least two particle types include a plurality of zwitterion molecules.

10. The method according to claim 1, after first biasing, further including:
second biasing between the second and third electrodes under conditions to separate a second particle type from the fluid.

11. The method according to claim 1, after at least one of first biasing and Nth biasing, further including:
analyzing at least one of the first particle type and the Nth particle type by a method selected from quantitative analysis, qualitiative analysis, and a combination thereof.

12. The method according to claim 1, wherein the device further includes:
a fluid source reservoir into which is disposed the first electrode;
a fluid receptacle reservoir into which is disposed the third electrode; and
wherein the conduit communicates between the fluid source reservoir and the fluid receptacle reservoir.

13. A device, comprising:
a conduit disposed in a dielectric structure;
a fluid source reservoir disposed at a first end of the conduit;
a fluid receptacle reservoir disposed at a second end of the conduit;
an optional first electrode disposed in the fluid source reservoir and spaced apart from the first end of the conduit;
a second electrode spaced apart from the first electrode and disposed either in the fluid source reservoir proximate the conduit, or in the conduit proximate the fluid source reservoir;
a third electrode disposed in the fluid receptacle reservoir and space apart from the second end of the conduit.

14. The device according to claim 13, further including:
a fluid-moving device connected to the device.

15. The device according to claim 13, wherein the dielectric includes:
a first layer including a channel disposed therein; and
a second layer disposed above the first layer.

16. The device according to claim 13, wherein the conduit includes a liner that resists electroosmosis.

17. The device according to claim 13, wherein the conduit includes a hydroxypropyl methyl cellulose liner.

18. A system for classifying at least two charged particle types comprising:
a device, including:
a conduit disposed in a dielectric structure;
a fluid source reservoir disposed at a first end of the conduit;
a fluid receptacle reservoir disposed at a second end of the conduit;
an optional first electrode disposed in the fluid source reservoir and spaced apart from the first end of the conduit;
a second electrode spaced apart from the first electrode and disposed either in the fluid source reservoir proximate the conduit, or in the conduit proximate the fluid source reservoir;
a third electrode disposed in the fluid receptacle reservoir and space apart from the second end of the conduit;
a fluid containing the at least two charged particle types, wherein the fluid is pH buffered, and wherein the fluid is disposed in the fluid source reservoir;
a blank fluid disposed in the conduit and in the fluid receptacle reservoir; and
a fluid mover for creating a convective force in the conduit.

19. The system according to claim 18, wherein the at least two charged particle types include at least two zwitterions.

20. The system according to claim 18, wherein the at least two charged particle types include at least two mammalian body serum particle types.

21. The system according to claim 18, wherein the dielectric structure is selected from an inorganic dielectric, an organic dielectric, and a semiconductive dielectric.

22. A process of making a particle classifier comprising:
forming a conduit including a first end and a second end in a dielectric structure;
forming a first fluid source reservoir at the first end;
forming a first fluid receptacle reservoir at the second end;
forming an optional first electrode in the first fluid source reservoir and spaced apart from the first end;
forming a second electrode either in the first fluid source reservoir proximate the conduit, or in the conduit proximate the first fluid source reservoir;
forming a third electrode in the first fluid receptacle reservoir and spaced apart from the second end.

23. The process according to claim 22, wherein forming a conduit includes:
etching a channel in a first substrate;
covering the first substrate with a second substrate; and
optionally treating the channel with a neutralizing process.

24. The process according to claim 22, wherein forming a conduit includes:
etching a channel in a first substrate;
covering the first substrate with a second substrate; and
optionally treating the channel with a neutralizing process; and further including:
etching the first fluid source reservoir and the first fluid receptacle reservoir through second substrate;
forming the second electrode by deposition in the first fluid source reservoir and upon the second substrate; and
optionally forming the third electrode by deposition in the first fluid receptacle reservoir and upon the second substrate.

25. The process according to claim 22, further including:
forming a second fluid source reservoir;
forming a second fluid receptacle reservoir;
forming a fourth electrode in the second fluid source reservoir; and
forming a fifth electrode in the second fluid receptacle reservoir.
